(19) United States
(12) Patent Application Publication
(10) Pub. No.: US 2017/0090607 A1
(43) Pub. Date: Mar. 30, 2017

(54) ONE-GLASS-SOLUTION TOUCH PANEL, ITS MANUFACTURING METHOD AND DISPLAY DEVICE

(71) Applicants: BOE TECHNOLOGY GROUP CO., LTD., Beijing (CN); HEFEI XINSHENG OPTOELECTRONICS TECHNOLOGY CO., LTD., Anhui (CN)

(72) Inventors: Lei ZHANG, Beijing (CN); Ming HU, Beijing (CN); Qingpu WANG, Beijing (CN); Wenjin FAN, Beijing (CN); Jun LI, Beijing (CN); Qicheng CHEN, Beijing (CN)

(73) Assignees: BOE TECHNOLOGY GROUP CO., LTD., Beijing (CN); HEFEI XINSHENG OPTOELECTRONICS TECHNOLOGY CO., LTD ., Anhui (CN)

(21) Appl. No.: 15/155,649

(22) Filed: May 16, 2016

(30) Foreign Application Priority Data
Sep. 24, 2015 (CN) 201510617923.6

(51) Int. Cl. G06F 3/041; H05K 3/46; H05K 3/22; H05K 1/02

(52) U.S. Cl. CPC G06F 3/041; H05K 1/0296; H05K 3/4644; H05K 3/22; H05K 1/0274; G06F 2203/04103; G06F 2203/04107; H05K 2201/0326

(57) ABSTRACT

The present disclosure provides an OGS touch panel, its manufacturing method and a display device. The OGS touch panel includes a substrate and a white light-shielding layer arranged on the substrate. The white light-shielding layer includes a white metal oxide.

### CROSS-REFERENCE TO RELATED APPLICATION

The present application claims a priority of the Chinese Patent Application No. 201510617923.6 filed on Sep. 24, 2015, which is incorporated herein by reference in its entirety.

### TECHNICAL FIELD

The present disclosure relates to the field of display technology, in particular to a One-Glass-Solution (OGS) touch panel, its manufacturing method, and a display device.

### BACKGROUND

An OGS touch panel is light and thin, and has excellent light transmittance, so it has gradually become a mainstream product in the touch panel industry.

The OGS touch panel mainly includes a white OGS touch panel and a black OGS touch panel. For the white OGS touch panel, usually a white light-shielding layer is manufactured in two ways. In one way, the white light-shielding layer is manufactured with white ink by screen-printing, and then wires are manufactured subsequently by photoetching. However, the resultant white light-shielding layer usually has a relatively large thickness, and the wires formed subsequently may easily be broken at a ramp, in addition, during the photoetching, it is difficult to perform alignment, and the yield of the touch panel may be adversely affected. In the other way, the whit light-shielding layer is manufactured with a white photoresist. However, the current white photoresist is of a relatively low optical density (OD), and even when it is of a large thickness, it is still impossible to achieve the ideal OD, At this time, a visual effect of the touch panel will be adversely affected.

### SUMMARY

An object of the present disclosure is to provide an OGS touch panel, its manufacturing method and a display device, so as to reduce a thickness of a white light-shielding layer of the OGS touch panel and improve a visual effect of the touch panel.

In one aspect, the present disclosure provides in some embodiments an OGS touch panel, including a substrate and a white light-shielding layer arranged on the substrate, The white light-shielding layer includes a white metal oxide.

Alternatively, the white light-shielding layer is a white metal oxide layer made of the white metal oxide.

Alternatively, the white metal oxide includes at least one of aluminium oxide, barium oxide and zinc oxide.

Alternatively, the white light-shielding layer has a thickness less than or equal to 10000 Å.

Alternatively, a protection layer and a touch function layer are sequentially arranged on the white light-shielding layer.

Alternatively, the touch function layer includes an indium tin oxide (ITO) electrode layer, a conductor layer and an insulation layer.

In another aspect, the present disclosure provides in some embodiments a display device including the above-mentioned touch panel.

In yet another aspect, the present disclosure provides in some embodiments a method for manufacturing an OGS touch panel, including a step of forming a white light-shielding layer on a substrate. The white light-shielding layer includes a white metal oxide.

Alternatively, the step of forming the white light-shielding layer on the substrate includes: forming a white metal oxide film on the substrate by a sputtering process; forming a pattern of a photoresist on the white metal oxide film, the pattern of the photoresist including a photoresist reserved region corresponding to a region where the white light-shielding layer is located and a photoresist unreserved region corresponding to the other region; removing the white metal oxide film at the photoresist unreserved region; and removing the remaining photoresist.

Alternatively, a target used by a sputtering process includes at least one of aluminium, aluminium oxide, barium, barium oxide, zinc and zinc oxide.

Alternatively, the sputtering process is conducted in the presence of argon and oxygen.

Alternatively, the white metal oxide film has a thickness less than or equal to 10000 Å.

Alternatively, subsequent to the step of forming the white light-shielding layer on the substrate, the method further includes forming a protection layer and a touch function layer sequentially on the white light-shielding layer.

According to the embodiments of the present disclosure, the white light-shielding layer of the OGS touch panel may be made of the white metal oxide by sputtering. As compared with the related art, it is able to reduce the thickness of the white light-shielding layer and prevent the occurrence of a wire breakage at a ramp. In addition, the white metal oxide has a relatively large OD, so it is able to increase the OD of the white light-shielding layer as well as the whiteness thereof, thereby to improve a visual effect of the touch panel even when the white light-shielding layer has a relatively small thickness.

### BRIEF DESCRIPTION OF THE DRAWINGS

FIG. 1 is a schematic view showing an OGS touch panel according to one embodiment of the present disclosure; and

FIGS. 2-7 are schematic views showing the manufacture of the OGS touch panel according to one embodiment of the present disclosure.

### DETAILED DESCRIPTION OF THE EMBODIMENTS

In order to make the objects, the technical solutions and the advantages of e present disclosure more apparent, the present disclosure will be described hereinafter in a clear and complete manner in conjunction with the drawings and embodiments. Obviously, the following embodiments merely relate to apart of, rather than all of, the embodiments of the present disclosure, and based on these embodiments, a person skilled in the art may, without any creative effort, obtain the other embodiments, which also fall within the scope of the present disclosure.

Unless otherwise defined, any technical or scientific term used herein shall have the common meaning understood by a person of ordinary skills. Such words as “first” and “second” used in the specification and claims are merely used to differentiate different components rather than to represent any order, number or importance. Similarly, such words as “one” or “one of” are merely used to represent the existence of at least one member, rather than to limit the number thereof. Such words as “connect” or “connected to” may include electrical connection, direct or indirect, rather than to be limited to physical or mechanical connection. Such words as “on”, “under”, “left” and “right” are merely used to represent relative position relationship, and when an absolute position of the object is changed, the relative position relationship will be changed too.

The present disclosure provides in some embodiments an OGS touch panel, which includes a substrate and a white light-shielding layer arranged on the substrate. The white light-shielding layer includes a white metal oxide.

According to the embodiments of the present disclosure, the white light-shielding layer of the OGS touch panel may be made of the white metal oxide by sputtering. As compared with the related art, it is able to reduce a thickness of the white light-shielding layer and prevent the occurrence of a wire breakage at a ramp. In addition, the white metal oxide has a relatively large OD, so it is able to increase the OD of the white light-shielding layer as well as the whiteness thereof, thereby to improve a visual effect of the touch panel even when the white light-shielding layer has a relatively small thickness.

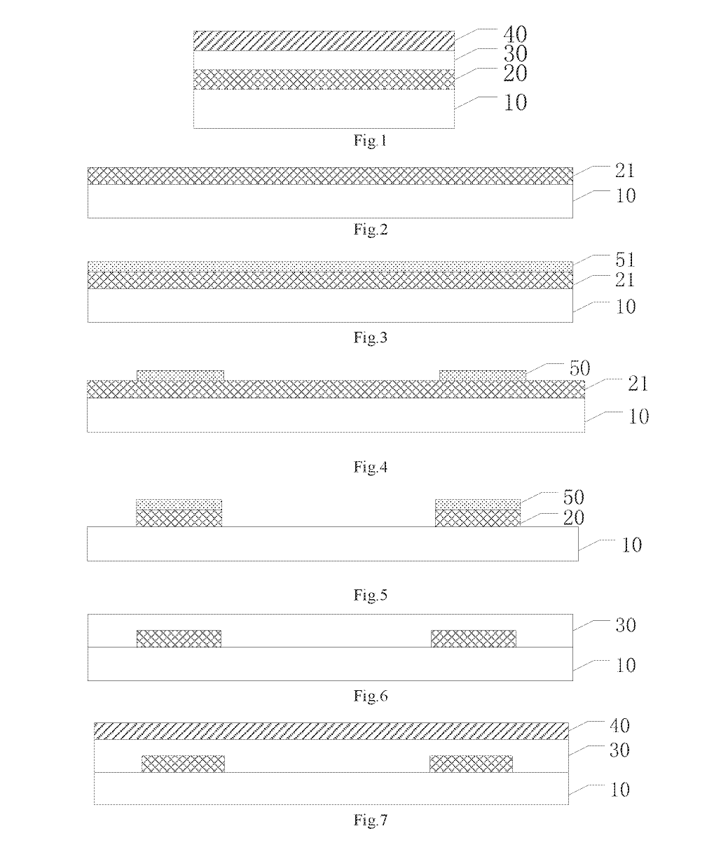

Referring to FIG. 1, the OGS touch panel includes the substrate 10, and the white light-shielding layer 20, a protection layer 30 and a touch function layer (a TP layer) 40 sequentially arranged on the substrate 10.

The white light-shielding layer 20 is made of the white metal oxide. Alternatively, the white metal oxide may include at least one of aluminium oxide, barium oxide and zinc oxide.

Alternatively, the white light-shielding layer 20 may have a thickness less than or equal to 10000 Å. In addition, in order to prevent a large amount of the white metal oxide in the white light-shielding layer 20 from being crystallized and thereby prevent the entire white light-shielding layer from being change from a white state into a transparent state, the thickness of the white light-shielding layer 20 may be increased appropriately, e.g., 8000 Å, 9000 Å or 10000 Å.

In addition, in the embodiments of the present disclosure, the touch function layer 40 may include an ITO electrode layer, a conductor layer and an insulation layer. The structure of the touch function layer is not particularly defined herein, as long as it may be used to achieve a touch function.

In addition, FIG. 1 merely shows the relationship between the white light-shielding layer and the other structure of the touch panel, but does not show shapes or patterns of the structures of the touch panel. In the embodiments of the present disclosure, the shape or pattern of the white light-shielding layer is not particularly defined, and it may be set in accordance with the practical need.

The present disclosure further provides in some embodiments a display device including the above-mentioned touch panel. The display device may be any product or member having a display function, such a laptop computer, a display, a television, a digital photo frame, a mobile phone or a flat-panel computer.

The present disclosure further provides in some embodiments a method for manufacturing an OGS touch panel, which includes a step of forming a white light-shielding layer on a substrate. The white light-shielding layer includes a white metal oxide.

To be specific, the method for manufacturing the OGS touch panel in the embodiments of the present disclosure may include the following steps S1 to S3.

S1: forming the white light-shielding layer made of the white metal oxide on the substrate. This step may include the following steps S11 to S14.

S11: as shown in FIG. 2, forming a white metal oxide film 21 on the substrate 10 by a sputtering process. The white metal oxide film 21 may have a thickness less than or equal to 10000 Å. A target used by the sputtering process may include at least one of aluminium, aluminium oxide, barium, barium oxide, zinc or zinc oxide. In the case that aluminium, barium or zinc is used as the target, oxygen at an appropriate amount may be introduced for the sputtering process, so as to form the corresponding white metal oxide on the substrate 10. Usually, the film formed by the sputtering process has a thickness not greater than 10000 Å, so the thickness of the white metal oxide film 21 formed by the sputtering process is far less than a thickness of a film formed by a white photoresist in the related art. As a result, it is able to effectively prevent a wire formed subsequently from being broken at a ramp.

In addition, in order to prevent a large amount of the white metal oxide from being crystallized and thereby prevent the entire white light-shielding layer from being changed from a white state into a transparent sate, an atmosphere and a temperature for the sputtering process may be adjusted appropriately. For example, the sputtering process may be conducted in the presence of argon and oxygen at a temperature of less than 200° C. In addition, the thickness of the white light-shielding layer may be increased appropriately, so as to prevent the entire white light-shielding layer from being changed from the White state into the transparent state. For example, the white light-shielding layer may have a thickness of 8000 Å, 9000 Å or 10000 Å.

S12: forming a pattern of a photoresist on the white metal oxide film, the pattern of the photoresist including a photoresist reserved region corresponding to a region where the white light-shielding layer is located and a photoresist unreserved region corresponding to the other region. To be specific, as shown in FIG. 3, the photoresist may be applied onto the white oxide film 21, so as to form a photoresist layer 51. Then, the photoresist layer 51 may be exposed and developed, so as to form the photoresist pattern 50 on the White metal oxide film 21, as shown in FIG. 4. The photoresist reserved region of the photoresist pattern 50 corresponds to the white light-shielding layer to be formed, and the photoresist unreserved region corresponds to the region other than the white light-shielding layer.

S13: removing the white metal oxide film at the photoresist unreserved region with an acidic solution. To be specific, as shown in FIG. 5, the white metal oxide film 21 at an exposed region (i.e., the photoresist unreserved region) may be etched, so as to form the white light-shielding layer 20 with the desired pattern.

S14: removing the remaining photoresist.

S2: forming a protection layer on the white light-shielding layer. To be specific, as shown in FIG. 6, an organic photoetching material (an over-coat (OC) material) may be applied onto an entire surface of the substrate 10 obtained after S1, and then solidified to form the protection layer (planarization layer) 30.

S3: as shown in FIG. 7, forming a touch function layer 40 on the protection layer 30.

According to the method in the embodiments of the present disclosure, the white light-shielding layer of the OGS touch panel may be made of the white metal oxide by sputtering. As compared with the elated art, it is able to reduce the thickness of the white light-shielding layer and prevent the occurrence of a wire breakage at a ramp. In addition, the white metal oxide has a relatively large OD, so it is able to increase the OD of the white light-shielding layer as well as the whiteness thereof, thereby to improve a visual effect of the touch panel even when the white light-shielding layer has a relatively small thickness.

The above are merely the preferred embodiments of the present disclosure. It should be appreciated that, a person skilled in the art may make further modifications and improvements without departing from the spirit of the present disclosure, and these modifications and improvements shall also fall within the scope of the present disclosure.

What is claimed is:

1. A One-Glass-Solution (OGS) touch panel, comprising a substrate and a white light-shielding layer arranged on the substrate, wherein the white light-shielding layer comprises a white metal oxide.

2. The OGS touch panel according to claim 1, wherein the white light-shielding layer is a white metal oxide layer made of the white metal oxide.

3. The OGS touch panel according to claim 1, wherein the white metal oxide comprises at least one of aluminium oxide, barium oxide and zinc oxide.

4. The OGS touch panel according to claim 1, wherein the white light-shielding layer has a thickness less than or equal to 10000 Å.

5. The OGS touch panel according to claim 1, wherein a protection layer and a touch function layer are sequentially arranged on the white light-shielding layer.

6. The OGS touch panel according to claim 5, wherein the touch function layer comprises an indium tin oxide (ITO) electrode layer, a conductor layer and an insulation layer.

7. A display device comprising the OGS touch panel according to claim 1.

8. The display device according to claim 7. Wherein the white light-shielding layer is a white metal oxide layer made of the white metal oxide.

9. The display device according to claim 7, wherein the white metal oxide comprises at least one of aluminium oxide, barium oxide and zinc oxide.

10. The display device according to claim 7, wherein the white light-shielding layer has a thickness less than or equal to 10000 Å.

11. The display device according to claim 7, wherein a protection layer and a touch function layer are sequentially arranged on the white light-shielding layer.

12. The display device according to claim 11, wherein the touch function layer comprises an indium tin oxide (ITO) electrode layer, a conductor layer and an insulation layer.

13. A method for manufacturing a One-Glass-Solution (OGS) touch panel, comprising a step of forming a white light-shielding layer on a substrate, wherein the white light-shielding layer comprises a white metal oxide.

14. The method according to claim 13, wherein the step of forming the white light-shielding layer on the substrate comprises:
forming a white metal oxide film on the substrate by a sputtering process;
forming a pattern of a photoresist on the white metal oxide film, the pattern of the photoresist comprising a photoresist reserved region corresponding to a region where the white light-shielding layer is located and a photoresist unreserved region corresponding to the other region;
removing the white metal oxide film at the photoresist unreserved region; and removing the remaining photoresist.

15. The method according to claim 14, wherein a target used by a sputtering process comprises at least one of aluminium, aluminium oxide, barium, barium oxide, zinc and zinc oxide.

16. The method according to claim 14, wherein the sputtering process is conducted in the presence of argon and oxygen.

17. The method according to claim 14, wherein the white metal oxide film has a thickness less than or equal to 10000 Å.

18. The method according to claim 13, wherein subsequent to the step of forming the white light-shielding layer on the substrate, the method further comprises forming a protection layer and a touch function layer sequentially on the white light-shielding layer.
